(19) United States
(12) Patent Application Publication
(10) Pub. No.: US 2022/0368301 A1
(43) Pub. Date: Nov. 17, 2022

(54) METHOD OF MANUFACTURING COLLECTIVE SUBSTRATE AND COLLECTIVE SUBSTRATE

(71) Applicant: Murata Manufacturing Co., Ltd., Nagaokakyo-shi (JP)

(72) Inventors: Masakazu FUKUMITSU, Nagaokakyo-shi (JP); Taku KAMOTO, Nagaokakyo-shi (JP)

(21) Appl. No.: 17/869,970

(22) Filed: Jul. 21, 2022

Related U.S. Application Data
(63) Continuation of application No. PCT/JP2020/042115, filed on Nov. 11, 2020.

(30) Foreign Application Priority Data
Apr. 9, 2020 (JP) 2020-070182

(51) Int. Cl. H03H 3/007; H03H 9/10; H03H 9/24

(52) U.S. Cl. CPC H03H 3/0072; H03H 9/1057; H03H 9/2489

(57) ABSTRACT

A method of manufacturing a collective substrate that includes: forming at least one first mark in or on a first main surface of a first substrate; joining the first main surface of the first substrate and a first main surface of a second substrate to each other; forming an opening in the second substrate such that the first mark is exposed therein; and forming a device portion in or on a second main surface of the second substrate while using the first mark as a reference.

### CROSS REFERENCE TO RELATED APPLICATIONS

The present application is a continuation of International application No. PCT/JP2020/042115, filed Nov. 11, 2020, which claims priority to Japanese Patent Application No. 2020-070182, filed Apr. 9, 2020, the entire contents of each of which are incorporated herein by reference.

### FIELD OF THE INVENTION

The present invention relates to a method of manufacturing a collective substrate, and a collective substrate.

### BACKGROUND OF THE INVENTION

In the related art, devices that are manufactured by using micro-electromechanical systems (MEMS) technology have become popular. These devices are formed by, for example, forming a plurality of devices onto a collective substrate (a wafer) and dividing and separating the wafer into the individual devices (chips).

For example, Patent Document 1 discloses a resonance device that is manufactured by using a cavity SOI (hereinafter also referred to as “CSOI”), which is a SOI wafer that has a cavity. In Patent Document 1, the CSOI includes a first substrate that serves as a bottom cover of the resonance device and a second substrate that serves as a resonator.
Patent Document 1: International Publication No. 2016/174789

### SUMMARY OF THE INVENTION

In the case of using a CSOI as in Patent Document 1, it is necessary to form a device portion including a device pattern and so forth onto a surface of a second substrate while a cavity that is formed in a first substrate is used as a reference. Thus, for example, a method has been employed. In this method, an alignment mark is formed beforehand on the surface of the first substrate, and the second substrate is joined to the first substrate. Then, infrared rays are used in order to visually recognize the alignment mark of the first substrate from the surface of the second substrate, and the device pattern is positioned, that is, alignment of the device pattern is performed, while the alignment mark is used as a reference.

In the method of the related art, however, it is difficult to accurately determine the position of the alignment mark. Thus, the alignment accuracy of the device portion that is formed on the basis of the alignment mark is low.

The present invention has been made in view of the above situation, and it is an object of the present invention to provide a method of manufacturing a collective substrate and a collective substrate capable of improving the alignment accuracy of a device portion.

A method of manufacturing a collective substrate according to an aspect of the invention includes: forming at least one first mark in or on a first main surface of a first substrate; joining the first main surface of the first substrate and a first main surface of a second substrate to each other; forming an opening in the second substrate such that the first mark is exposed therein; and forming a device portion in or on a second main surface of the second substrate while using the first mark as a reference.

A collective substrate according to another aspect of the invention includes: a first substrate having at least one first mark in or on a first main surface thereof; and a second substrate joined to the first main surface of the first substrate, wherein the second substrate has an opening therein at a position that corresponds to the first mark.

According to the present invention, the alignment accuracy of a device portion can be improved.

### BRIEF DESCRIPTION OF THE DRAWINGS

FIG. 1 is an exploded perspective view schematically illustrating the appearance of a collective substrate 100 in an embodiment.

FIG. 2 is a flowchart illustrating a method of manufacturing a collective substrate in an embodiment.

FIG. 3 is a sectional view for depicting a step illustrated in FIG. 2.

FIG. 4 is a sectional view for depicting a step illustrated in FIG. 2.

FIG. 5 is a plan view for depicting a first mark illustrated in FIG. 4.

FIG. 6 is a sectional view for depicting a step illustrated in FIG. 2.

FIG. 7 is a sectional view for depicting a step illustrated in FIG. 2.

FIG. 8 is a sectional view for depicting an example of a step illustrated in FIG. 2.

FIG. 9 is a sectional view for depicting another example of the step illustrated in FIG. 2.

FIG. 10 is a sectional view for depicting a step illustrated in FIG. 2.

FIG. 11 is a plan view illustrating the schematic structure of a collective substrate that is manufactured by using the manufacturing method illustrated in FIG. 2.

FIG. 12 is a perspective view schematically illustrating the appearance of a resonance device in an embodiment.

FIG. 13 is an exploded perspective view for depicting the schematic structure of the resonance device illustrated in FIG. 12.

FIG. 14 is a plan view for depicting the schematic structure of a resonator illustrated in FIG. 12.

FIG. 15 is a sectional view taken along line XV-XV of FIG. 12 to FIG. 14 for depicting the schematic structure of the resonance device illustrated in FIG. 12 to FIG. 14.

### DETAILED DESCRIPTION OF THE PREFERRED EMBODIMENTS

Embodiments of the present invention will be described below. In the drawings that will be referred to in the following description, the same or similar components will be denoted by the same or similar reference signs. The drawings are examples and schematically illustrate the dimensions and the shapes of the components, and the technical scope of the present invention should not be considered to be limited to the embodiments.

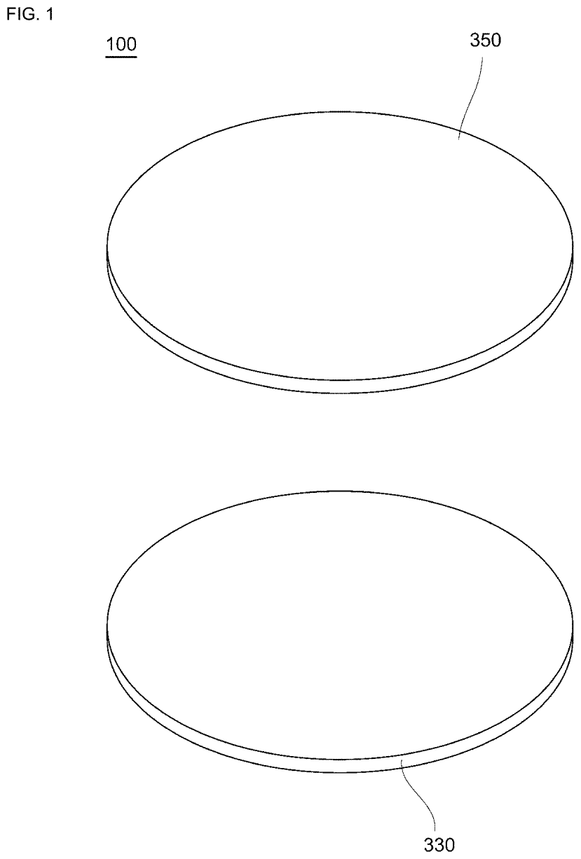

First, the schematic structure of a collective substrate according to an embodiment of the present invention will be described with reference to FIG. 1. FIG. 1 is an exploded perspective view schematically illustrating the appearance of a collective substrate 100 in an embodiment.

The collective substrate 100 of the present embodiment is used for manufacturing a MEMS device, which will be described later. As illustrated in FIG. 1, the collective substrate 100 includes a first substrate 330 and a second substrate 350. The collective substrate 100 has a multilayer structure in which the second substrate 350 is joined to an upper surface of the first substrate 330. The first substrate 330 and the second substrate 350 each have a circular shape or a substantially circular shape when viewed in plan view.

Note that the collective substrate 100 may further include a third substrate, which is not illustrated. In this case, the collective substrate 100 has a multilayer structure in which the third substrate is joined to an upper surface of the second substrate 350.

The collective substrate 100 usually includes a plurality of MEMS devices. The plurality of MEMS devices can be manufactured by dividing the collective substrate 100 along dividing lines. The dividing lines are used for dividing the collective substrate 100 into pieces by cutting or the like and are also called scribe lines. The width of each dividing line is, for example, 5 μm to 20 μm.

The collective substrate 100 may be divided into pieces through a dicing process that is performed by cutting the first substrate 330 and the second substrate 350 with a dicing saw or through a dicing process that is performed by using a stealth dicing technology for forming a modified layer into at least one of the first substrate 330 and the second substrate 350 by converging a laser beam.

By dividing the collective substrate 100 into pieces in the manner described above, the collective substrate 100 is separated into the individual MEMS devices (chips), and the MEMS devices each of which includes the first substrate 330 and the second substrate 350 are manufactured. Note that the collective substrate 100 may be divided into pieces after joining the above-mentioned third substrate. In this case, the third substrate corresponds to a bottom cover 20 of a resonance device 1, which will be described later.

As a result of the collective substrate 100 further including the third substrate that is joined to the upper surface of the second substrate 350 as mentioned above, the resonance device 1 (described later) that includes the first substrate 330 and the second substrate 350 and further includes the third substrate can be manufactured.

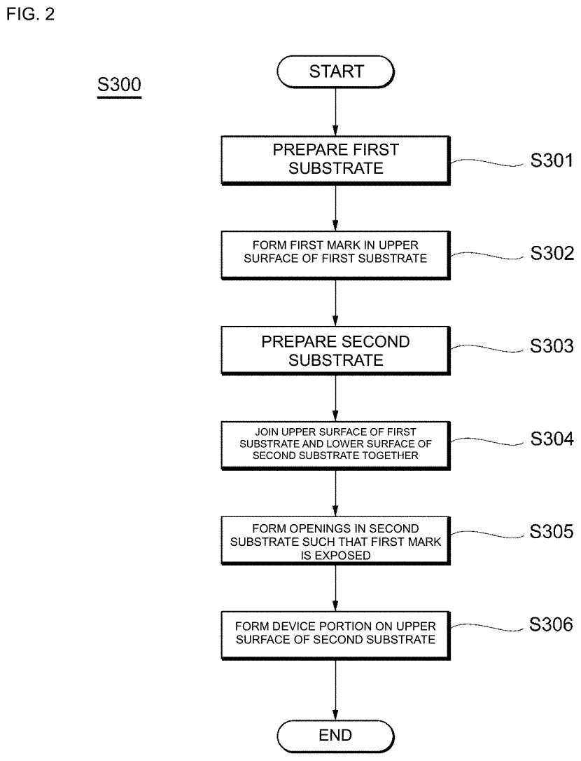

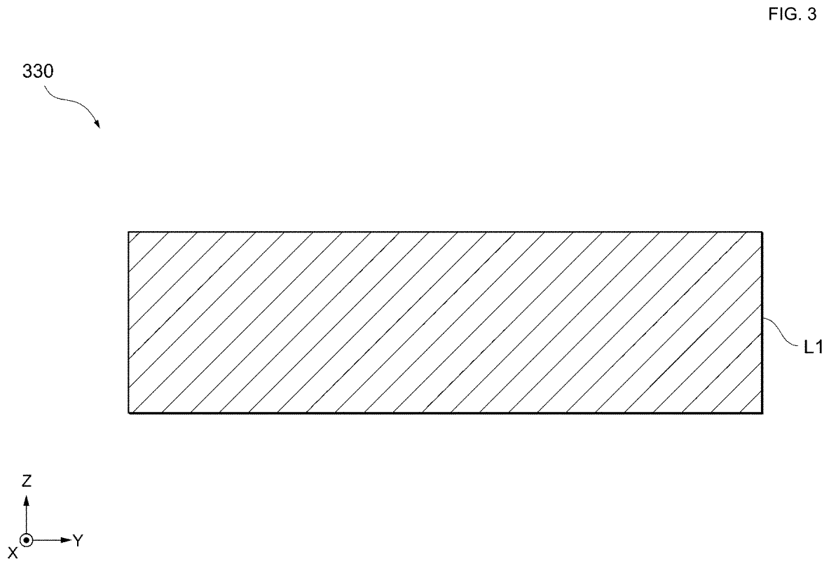

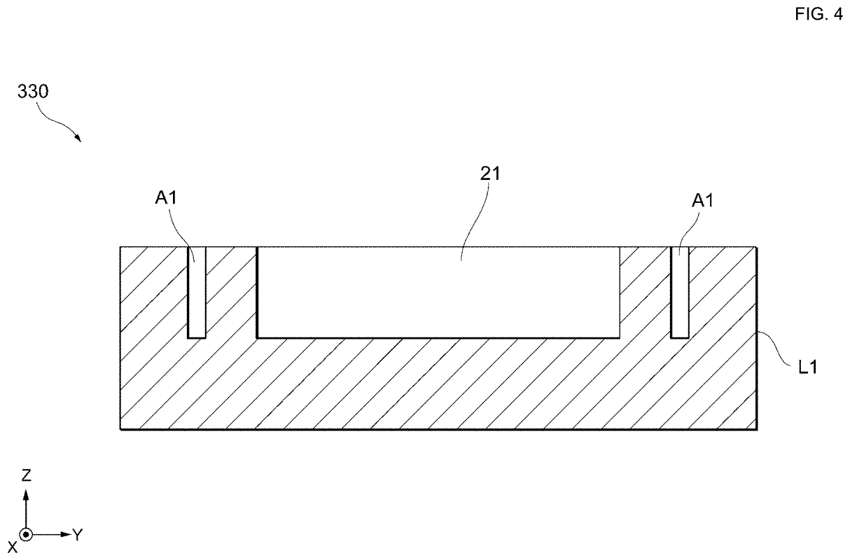

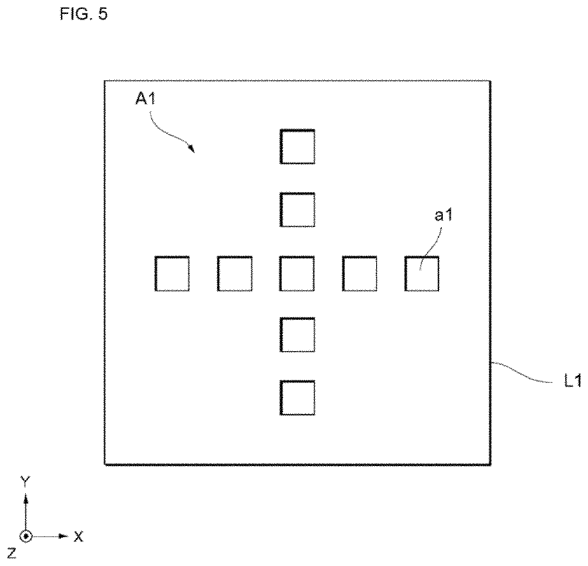

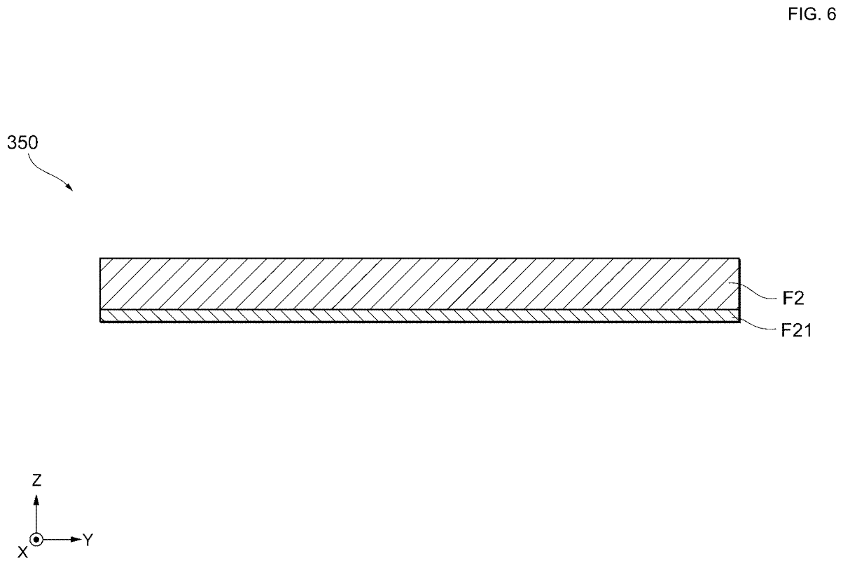

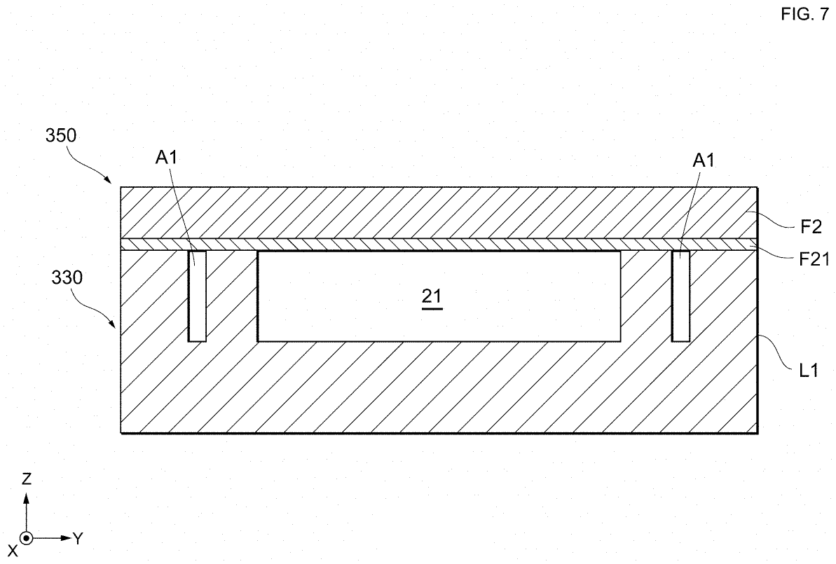

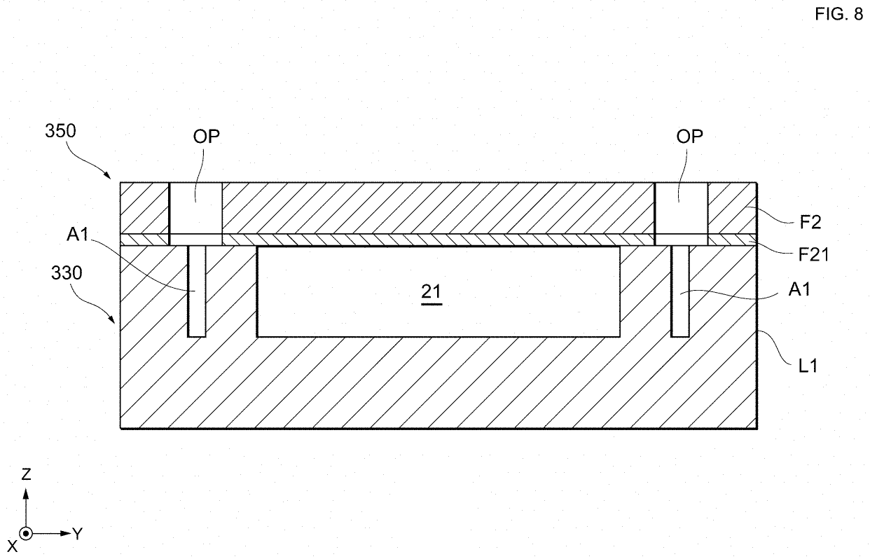

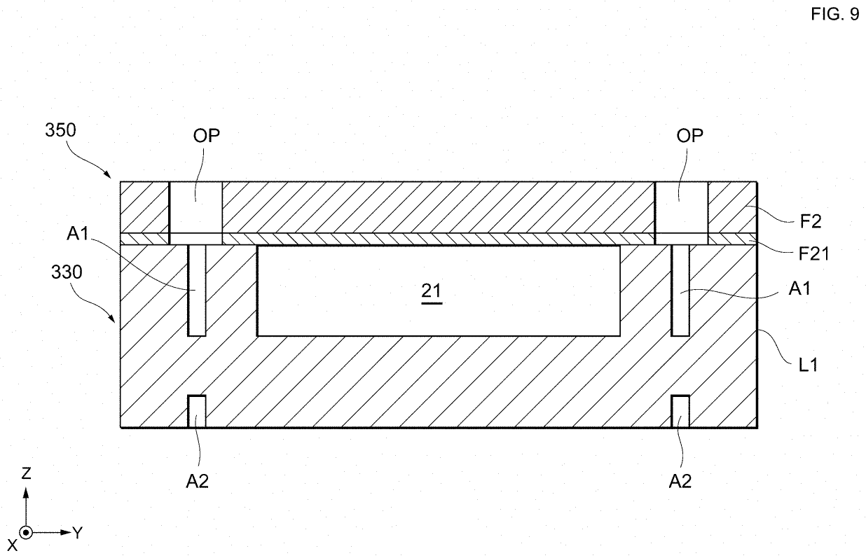

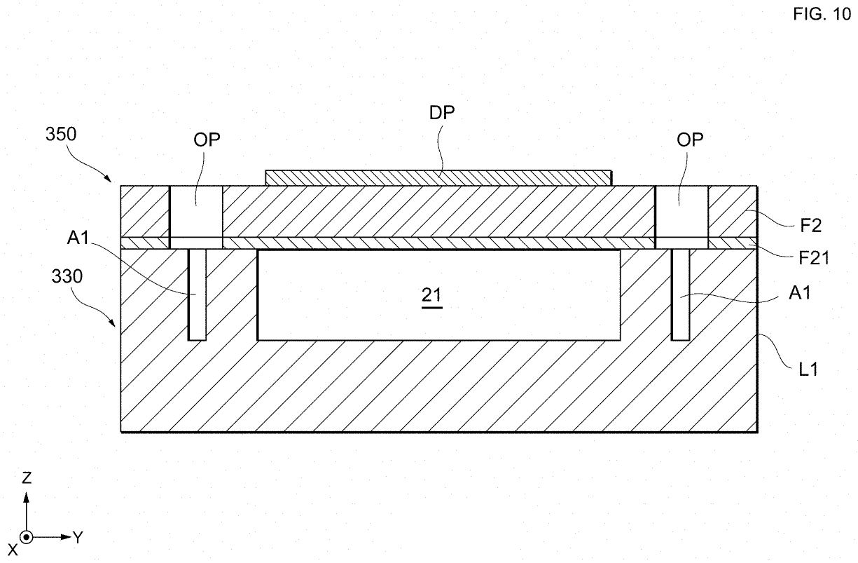

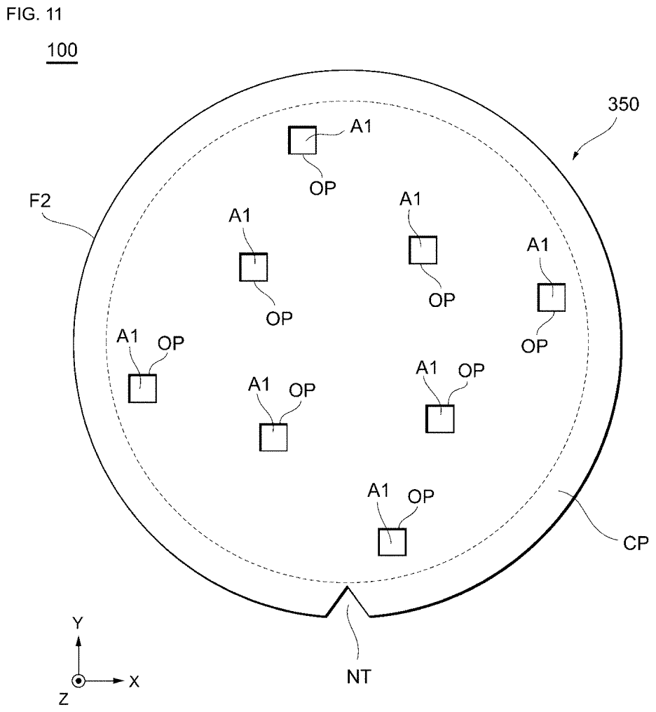

Next, a method of manufacturing a collective substrate according to an embodiment will be described with reference to FIG. 2 to FIG. 11. FIG. 2 is a flowchart illustrating a method of manufacturing the collective substrate 100 in an embodiment. FIG. 3 is a sectional view for depicting step S301 illustrated in FIG. 2. FIG. 4 is a sectional view for depicting step S302 illustrated in FIG. 2. FIG. 5 is a plan view for depicting a first mark A1 illustrated in FIG. 4. FIG. 6 is a sectional view for depicting step S303 illustrated in FIG. 2. FIG. 7 is a sectional view for depicting step S304 illustrated in FIG. 2. FIG. 8 is a sectional view for depicting an example of step S305 illustrated in FIG. 2. FIG. 9 is a sectional view for depicting another example of step S305 illustrated in FIG. 2. FIG. 10 is a sectional view for depicting step S306 illustrated in FIG. 2. FIG. 11 is a plan view illustrating the schematic structure of the collective substrate 100 that is manufactured by using a manufacturing method S300 illustrated in FIG. 2. Note that, for convenience of description, FIG. 3 to FIG. 11 only illustrate some of a plurality of MEMS devices that are manufactured by using the collective substrate 100.

In the following description, the resonance device 1 that includes the bottom cover 20, a resonator 10, and a top cover 30 will be described as an example of as a MEMS device. Note that a MEMS device that is manufactured by using the collective substrate 100 is not limited to the resonance device 1.

In the following description, the positive Z-axis direction is defined as an upward (or forward) direction, and the negative Z-axis direction is defined as a downward (or rearward) direction.

As illustrated in FIG. 2, the first substrate 330 that corresponds to the bottom cover 20 of the resonance device 1 is prepared first (S301).

The first substrate 330 is formed by using a silicon (Si) substrate (hereinafter referred to as “Si substrate”). More specifically, as illustrated in FIG. 2, the first substrate 330 is formed of a silicon (Si) wafer (hereinafter referred to as “Si wafer”) L1. The thickness of the Si wafer L1 is, for example, about 150 μm. The Si wafer L1 is made of non-degenerate silicon (Si), and its resistivity is, for example, 16 mΩ·cm or more.

Next, returning to FIG. 2, a first mark is formed in the upper surface of the first substrate 330 (S302). Note that the upper surface of the first substrate 330 corresponds to an example of a “first main surface of a first substrate”, and a lower surface of the first substrate 330 corresponds to an example of a “second main surface of the first substrate”.

More specifically, as illustrated in FIG. 4, a recess (a cavity) 21 is formed in an upper surface of the Si wafer L1 first. The depth of the recess 21 is, for example, about 50 μm. Then, the first mark A1 is formed in the upper surface of the Si wafer L1 while the position of the recess 21 is used as a reference. The first mark A1 has a shape recessed from the upper surface of the Si wafer L1 when viewed in cross section. The recess 21 and the first mark A1 are each formed by removing a portion of the Si wafer L1 by, for example, processing such as etching.

As illustrated in FIG. 5, the first mark A1 has a plurality of rectangular openings al. The openings al are arranged in the shape of a cross when the upper surface of the first substrate 330, that is, the upper surface of the Si wafer L1 is viewed in plan view. The first mark A1 has a length of, for example, about 50 μm in the X-axis direction and the Y-axis direction.

Note that the recess 21 may be formed beforehand in step S301 or may be formed in step S302 as mentioned above. By forming the recess 21 in the upper surface of the first substrate 330 in the manner described above, the collective substrate 100, which is a CSOI, can be manufactured.

In addition, in step S302, a second mark A2, which will be described later, may be formed on a lower surface of the Si wafer L1 while the position of the first mark A1, which is formed in the upper surface, is used as a reference.

Next, returning to FIG. 2, the second substrate 350 that corresponds to the resonator 10 of the resonance device 1 is prepared (S303).

As illustrated in FIG. 6, the second substrate 350 includes a Si substrate F2 and a silicon oxide (e.g., SiO₂) layer F21.

The Si substrate F2 is formed by using, for example, a degenerate n-type silicon (Si) semiconductor having a thickness of about 6 μm and can contain phosphorus (P), arsenic (As), antimony (Sb), or the like as an n-type dopant. The resistance of degenerate silicon (Si) that is used for the Si substrate F2 is, for example, less than 16 mΩ·cm and preferably 1.2 mΩ·cm or less.

As an example of a temperature-characteristic correction layer, the silicon oxide (e.g., SiO₂) layer F21 is formed on a lower surface of the Si substrate F2. As a result, temperature characteristics can be improved. Note that the silicon oxide layer F21 may be formed on the upper surface of the Si substrate F2 or may be formed on both the upper surface and the lower surface of the Si substrate F2.

Next, returning to FIG. 2, the upper surface of the first substrate 330 and the lower surface of the second substrate 350 are joined together (S303). Note that the lower surface of the second substrate 350 corresponds to an example of a “first main surface of a second substrate”, and the upper surface of the second substrate 350 corresponds to an example of a “second main surface of the second substrate”.

As illustrated in FIG. 7, when the first substrate 330 and the second substrate 350 are joined together, the first mark A1 formed in the upper surface of the first substrate 330 is covered with the lower surface of the second substrate 350. Thus, the first mark A1 of the first substrate 330 cannot be visually observed from the upper surface of the second substrate 350. In addition, even in the case of using infrared light like the related art, the visibility of the first mark A1 is low, and it is difficult to accurately determine the position of the first mark A1.

Next, returning to FIG. 2, openings are formed in the second substrate 350 in such a manner that the first mark A1 of the first substrate 330 is exposed (S305).

More specifically, as illustrated in FIG. 8, a portion of the Si substrate F2 and a portion of the silicon oxide layer F21 that correspond to the first mark A1 are removed by etching or the like, and openings OP are formed so as to extend between the upper surface to the lower surface of the second substrate 350.

As described above, by forming the openings OP in the second substrate 350 in such a manner that the first mark A1 is exposed through the openings OP, the first mark A1 can actually be seen with the eyes, that is, the first mark A1 can be visually recognized.

Regarding the positions at which the openings OP are formed, for example, first, the position of the first mark A1 is derived from the external shapes of the first substrate 330 and the second substrate 350 when viewed in plan view. The phrase “external shapes of the first substrate 330 and the second substrate 350 when viewed in plan view” refers to, for example, the dimensions (the diameters) of the first substrate 330 and the second substrate 350 when viewed in plan view and characteristic structures of outer peripheral portions of the first substrate 330 and the second substrate 350 such as, for example, notches and orientation flats. The position of the first mark A1 can be easily derived from the information regarding the external shapes. Then, the openings OP are formed in the second substrate 350 on the basis of the derived position of the first mark A1. In this case, for example, each of the openings OP has a length of about 500 μm in the X-axis direction and the Y-axis direction.

As described above, the position of the first mark A1 is derived from the external shapes of the first substrate 330 and the second substrate 350 when viewed in plan view, and the openings OP are formed in the second substrate 350 on the basis of the derived position of the first mark A1, so that the position of the first mark A1 can be easily derived, and the manufacturing costs of the collective substrate 100 can be reduced.

The position of the first mark A1 is not limited to being derived from the external shapes of the first substrate 330 and the second substrate 350 when viewed in plan view. For example, the position of the first mark A1 of the first substrate 330 may be derived by radiating infrared light from the upper surface of the second substrate 350. In this case, by forming the openings OP in the second substrate 350 on the basis of the derived position of the first mark A1, the length of each of the openings OP in the X-axis direction and the length of each of the openings OP in the Y-axis direction can each be reduced to, for example, about 100 μm. As a result, the openings can be positioned with respect to the first mark A1 with high accuracy.

Alternatively, as illustrated in FIG. 9, the second mark A2 may be formed beforehand at a position in the lower surface of the first substrate 330, the position corresponding to the first mark A1, and the position of the first mark A1 formed in the upper surface of the first substrate 330 may be derived from the second mark A2. The second mark A2 has a shape recessed from the lower surface of the Si wafer L1 when viewed in cross section. The depth of the second mark A2 may be smaller than that of the first mark A1. Then, the openings OP are formed in the second substrate 350 on the basis of the derived position of the first mark A1, so that the length of each of the openings OP in the X-axis direction and the length of each of the openings OP in the Y-axis direction can each be reduced to, for example, about 100 μm. As a result, the openings can be positioned with respect to the first mark A1 with high accuracy.

Next, returning to FIG. 2, a device portion DP is formed on the upper surface of the second substrate 350 while the first mark A1 of the first substrate 330 is used as a reference (S306).

As illustrated in FIG. 10, the device portion DP is formed at a position on the upper surface of the second substrate 350, the position corresponding to the recess 21 of the first substrate 330. For example, the device portion DP includes an electrode, a pattern wiring line, and so forth of the resonator 10 of the resonance device 1. For example, a photolithography technique is used, and a surface coated with a photosensitive substance is exposed to light by using a photomask pattern, so that the device portion DP is formed.

Here, when the device portion DP is formed, the recess 21 of the first substrate 330 is covered with the lower surface of the second substrate 350 and cannot be visually recognized. However, the first mark A1 of the first substrate 330 that is exposed through the openings OP of the second substrate 350 can be visually recognized as mentioned above, and thus, the position of the first mark A1 can be accurately determined. Thus, by forming the device portion DP on the upper surface of the second substrate 350 while the first mark A1 is used as a reference, the alignment accuracy of the device portion DP with respect to the recess 21 can be improved.

As described above, the collective substrate 100 is manufactured by following the steps of the manufacturing method S300 illustrated in FIG. 2. As illustrated in FIG. 11, the manufactured collective substrate 100 has the openings OP, which are formed in the second substrate 350 at the positions that correspond to the first mark A1. As described above, although the openings OP are formed in such a manner that the first mark A1 is exposed therethrough, there is a possibility that the first mark A1 will not be exposed during the manufacturing process due to, for example, accumulation of deposits or the like. Even in such a case, each of the openings OP has a step that is more recessed than the upper surface of the second substrate 350, and the presence of the openings OP enables determination of the position of the first mark A1.

The collective substrate 100 may include a plurality of first marks A1. In this case, the plurality of first marks A1 are formed in the upper surface of the first substrate 330 in step S302. As a result, in the case of poor recognition of one of the first marks A1, another one of the first marks A1 can be used instead.

Preferably, four or more first marks A1 are formed in the upper surface of the first substrate 330 in step S302. In this case, it is further preferable that the first mark A1 be formed on an exposure-by-exposure basis in photolithography, that is, for each shot. In photolithography, for example, one shot has a length of about 2 cm in the X-axis direction and a length of about 2 cm in the Y-axis direction. By forming the four or more first marks A1 in the upper surface of the first substrate 330 in step S302 in the manner described above, in the case of poor recognition of one of the first marks A1, another one of the first marks A1 can easily be used instead.

In addition, in the collective substrate 100, it is preferable that the first mark A1 be positioned in a region that is located further toward the inside than an outer peripheral portion CP in a radial direction. The outer peripheral portion CP of the collective substrate 100 is, for example, a region extending from the outer edge of the collective substrate 100 so as to have a width of about 3 mm to about 5 mm. The outer peripheral portion CP may include a notch NT, an orientation flat (not illustrated), or the like. In this manner, the first mark A1 is formed in the region, which is inside the outer peripheral portion CP of the collective substrate 100 when the first substrate 330 is viewed in plan view, and is avoided from being formed in the outer peripheral portion CP, so that poor recognition of the first mark A1 due to scratches, contamination, or the like can be suppressed.

In the present embodiment, although a case has been described in which the collective substrate 100 has the recess 21 formed in the upper surface of the first substrate 330 and in which the device portion DP is aligned with the recess 21, the present invention is not limited to this embodiment. The device portion DP may be formed while using, as a reference, another structure such as, for example, a via or an electrode that is formed in or on the first substrate 330. In this case, the first mark A1 is formed at a predetermined position so as to be positioned with respect to the structure.

In addition, in the present embodiment, although a case has been described in which the collective substrate 100 includes the device portion DP formed on the upper surface of the second substrate 350, the present invention is not limited to this embodiment. The collective substrate 100 may at least have the openings OP that are formed in the second substrate 350 at positions that correspond to the first mark A1. After a collective substrate that does not include a device portion has been manufactured, for example, a device portion may be formed on an upper surface of a second substrate after shipment of the collective substrate.

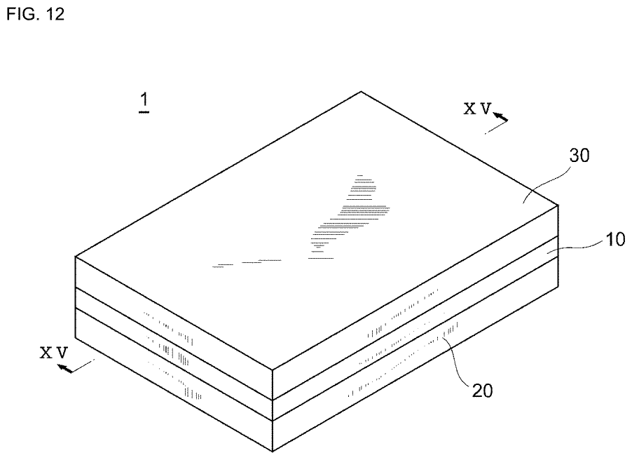

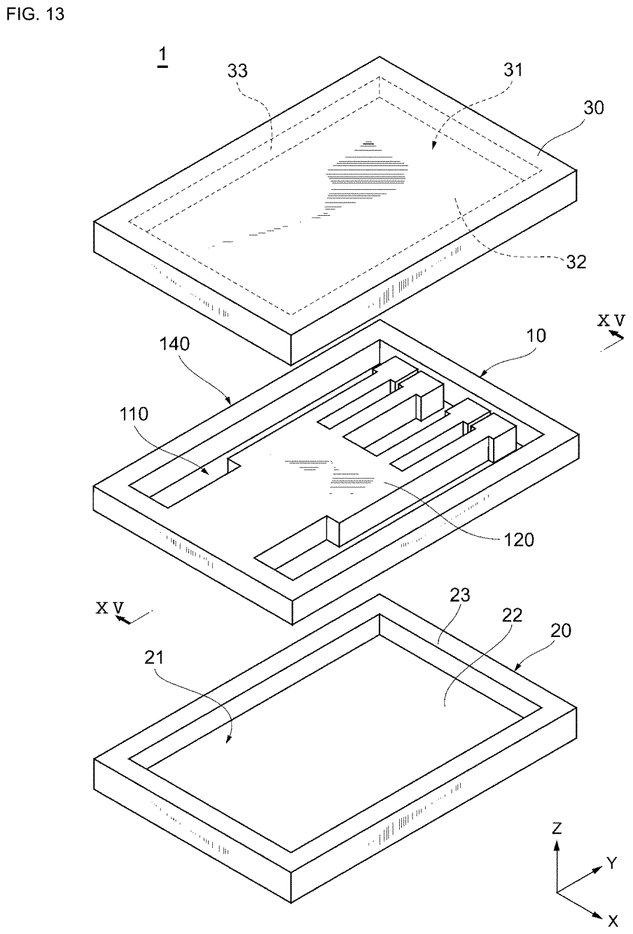

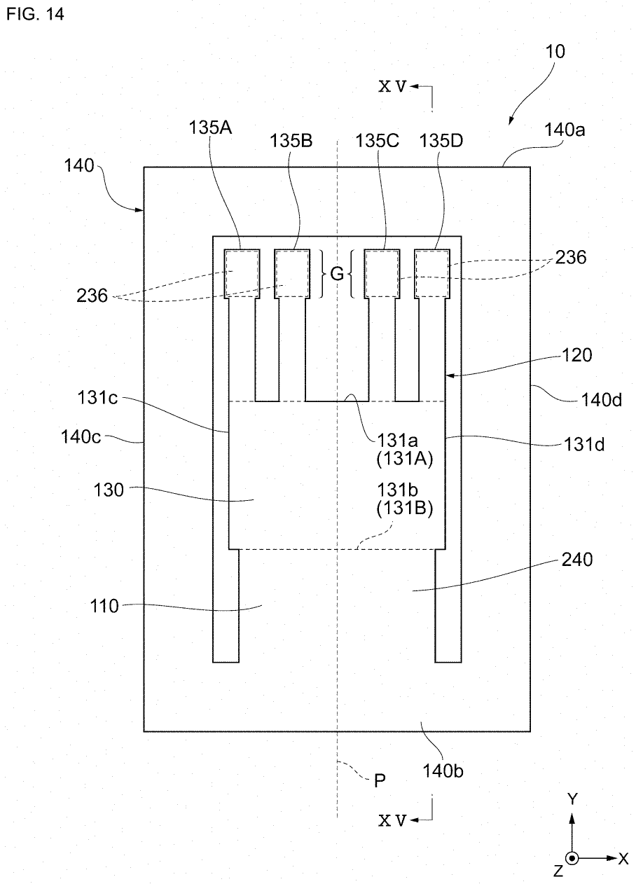

A resonance device that is manufactured by using a collective substrate according to an embodiment will now be described with reference to FIG. 12 to FIG. 15. FIG. 12 is a perspective view schematically illustrating the appearance of the resonance device 1 in an embodiment. FIG. 13 is an exploded perspective view for depicting the schematic structure of the resonance device 1 illustrated in FIG. 12. FIG. 14 is a plan view for depicting the schematic structure of the resonator 10 illustrated in FIG. 12.

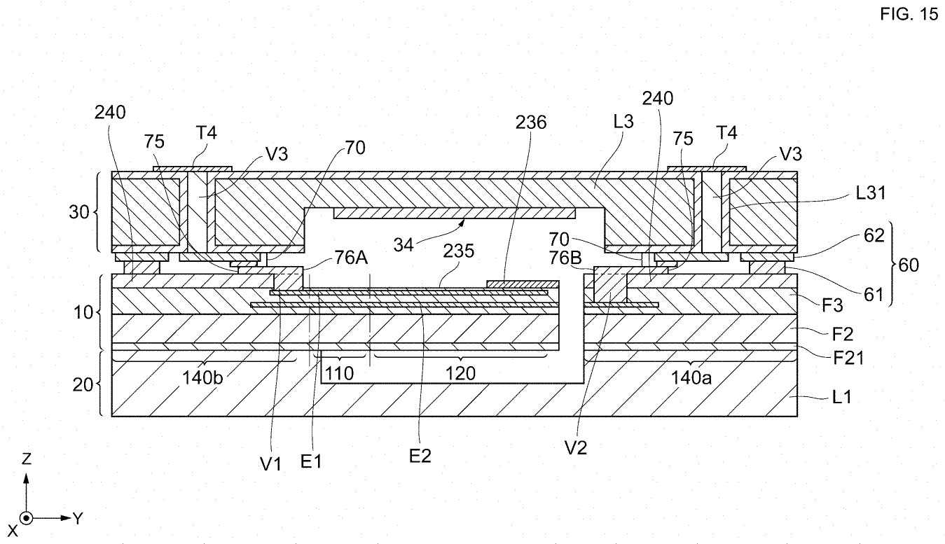

FIG. 15 is a sectional view taken along line XV-XV of FIG. 12 to FIG. 14 for depicting the schematic structure of the resonance device 1 illustrated in FIG. 12 to FIG. 14.

In the following description, the side of the resonance device 1 on which the top cover 30 is disposed is defined as the upper side (or the front side), and the side of the resonance device 1 on which the bottom cover 20 is disposed is defined as the lower side (or the rear side).

As illustrated in FIG. 12 and FIG. 13, the resonance device 1 includes the bottom cover 20, the resonator 10, and the top cover 30. In other words, the resonance device 1 includes the bottom cover 20, the resonator 10, a joint portion 60, which will be described later, and the top cover 30 laminated together in this order.

The resonator 10 is a MEMS vibrator that is manufactured by using MEMS technology. The resonator 10 and the top cover 30 are joined to each other with the joint portion 60 interposed therebetween.

The top cover 30 extends along an XY plane in such a manner as to have a flat plate-like shape, and a recess 31 that has, for example, a flat rectangular parallelepiped shape is formed in the rear surface of the top cover 30. The recess 31 is surrounded by a side wall 33 and forms part of a vibration space that is a space in which the resonator 10 vibrates. In addition, a getter layer 34 which will be described later is formed on a surface of the recess 31 of the top cover 30, the surface facing the resonator 10. Note that the top cover 30 may have a flat plate-like shape without the recess 31 formed therein.

The bottom cover 20 includes a bottom plate 22 that has a rectangular flat plate-like shape and that is arranged along the XY plane and a side wall 23 that extends from a peripheral edge portion of the bottom plate 22 in the Z-axis direction, that is, the direction in which the bottom cover 20 and the resonator 10 are laminated together. The bottom cover 20 has the above-mentioned recess 21 that is formed in a surface thereof facing the resonator 10 and that is defined by the front surface of the bottom plate 22 and the inner surface of the side wall 23. The recess 21 forms part of the vibration space of the resonator 10. Note that the bottom cover 20 may have a flat plate-like shape without the recess 21 formed therein. In addition, a getter layer may be formed on a surface of the recess 21 of the bottom cover 20, the surface facing the resonator 10.

As illustrated in FIG. 14, the resonator 10 is a MEMS vibrator that is manufactured by using MEMS technology and vibrates out of plane within the XY plane in the rectangular coordinate system illustrated in FIG. 14. Note that the resonator 10 is not limited to a resonator using an out-of-plane bending vibration mode. The resonator of the resonance device 1 may be, for example, one of vibrators that use an expansion vibration mode, a thickness longitudinal vibration mode, a Lamb-wave vibration mode, an in-plane bending vibration mode, and a surface-acoustic-wave vibration mode. These vibrators are applied to, for example, a timing device, an RF filter, a duplexer, an ultrasonic transducer, a gyro sensor, an acceleration sensor, and so forth. In addition, the vibrators may be used for a piezoelectric mirror having an actuator function, a piezoelectric gyro, a piezoelectric microphone having a pressure sensor function, an ultrasonic vibration sensor, and so forth. Furthermore, the vibrators may be applied to an electrostatic MEMS element, an electromagnetically-driven MEMS element, and a piezoresistance MEMS element.

The resonator 10 includes a vibrating portion 120, a holding portion 140, and a holding arm 110.

The holding portion 140 is formed in a rectangular frame-like shape extending along the XY plane so as to surround the outer side of the vibrating portion 120. For example, the holding portion 140 is integrally formed of a frame body in the form of a prism. Note that the holding portion 140 is not limited to having a frame-like shape as long as it is provided around at least part of the periphery of the vibrating portion 120.

The holding arm 110 is disposed in a space enclosed by the holding portion 140 and connects the vibrating portion 120 and the holding portion 140 to each other.

The vibrating portion 120 is disposed in the space enclosed by the holding portion 140, and a space is formed between the vibrating portion 120 and the holding portion 140 in such a manner that the vibrating portion 120 and the holding portion 140 are separated from each other by a predetermined distance. In the case illustrated in FIG. 14, the vibrating portion 120 includes a base portion 130 and four vibration arms 135A to 135D (hereinafter also collectively referred to as “vibration arms 135”). Note that the number of the vibration arms is not limited to four and is set to, for example, any number that is one or more. In the present embodiment, the vibration arms 135A to 135D and the base portion 130 are integrally formed with one another.

When viewed in plan view, the base portion 130 has long sides 131a and 131b in the X-axis direction and short sides 131c and 131d in the Y-axis direction. The long side 131a is one side of a front end surface (hereinafter also referred to as “front end 131A”) of the base portion 130, and the long side 131b is one side of a rear end surface (hereinafter also referred to as “rear end 131B”) of the base portion 130. In the base portion 130, the front end 131A and the rear end 131B are arranged so as to face each other.

The base portion 130 is connected to the vibration arms 135 at the front end 131A and connected to the holding arm 110, which will be described later, at the rear end 131B. Note that, in the case illustrated in FIG. 14, although the base portion 130 has a substantially rectangular shape when viewed in plan view, the shape of the base portion 130 is not limited to this. The base portion 130 may at least be formed substantially symmetrically with respect to a virtual plane P that is defined along a perpendicular bisector of the long side 131a. For example, the base portion 130 may have a trapezoidal shape in which the long side 131b is shorter than the long side 131a or may have a semicircular shape having the long side 131a as its diameter. In addition, each surface of the base portion 130 is not limited to a flat surface and may be a curved surface. Note that the virtual plane P is a plane that passes through the center of the vibrating portion 120 in the direction in which the vibrating arms 135 are arranged.

In the base portion 130, a base portion length that is the longest distance between the front end 131A and the rear end 131B in a direction from the front end 131A toward the rear end 131B is about 35 μm. In addition, a base portion width that is the longest distance between side ends of the base portion 130 in a width direction that is perpendicular to the base portion length direction is about 265 μm.

The vibration arms 135 extend in the Y-axis direction and have the same size. The vibration arms 135 are arranged parallel to one another in the Y-axis direction between the base portion 130 and the holding portion 140. One end of each of the vibration arms 135 is a fixed end by being connected to the front end 131A of the base portion 130, and the other end of each of the vibration arms 135 is an open end. In addition, the vibration arms 135 are arranged side by side in the X-axis direction at a predetermined pitch. Note that, for example, each of the vibration arms 135 has a width of about 50 μm in the X-axis direction and a length of about 465 μm in the Y-axis direction.

For example, each of the vibration arms 135 has a portion that has a length of about 150 μm from the corresponding open end and a width larger than that of the rest of the vibration arm 135 in the X-axis direction. This wider portion will be referred to as an anchor portion G. Each of the anchor portions G has, for example, a width that is transversely larger by 10 μm than that of the rest of the corresponding vibration arm 135 in the X-axis direction, and the width of each of the anchor portions G in the X-axis direction is about 70 μm. The anchor portions G are integrally formed with the vibration arms 135 through the same process. By forming the anchor portions G, the weight per unit length of each of the vibration arms 135 on the open end side is larger than that on the fixed end side. Thus, as a result of each of the vibration arms 135 including the anchor portion G on the open end side, the amplitude of vertical vibration of each vibration arm can be increased.

A protective film 235, which will be described later, is formed on a surface (the surface facing the top cover 30) of the vibrating portion 120 so as to cover the entire surface. In addition, a frequency adjustment film 236 is formed on a surface of the protective film 235 at the ends of the vibration arms 135A to 135D on the open end side. The resonant frequency of the vibrating portion 120 can be adjusted by the protective film 235 and the frequency adjustment film 236.

Note that, in the present embodiment, the surface (the surface facing the top cover 30) of the resonator 10 is almost entirely covered with the protective film 235. In addition, the surface of the protective film 235 is almost entirely covered with a parasitic capacitance reducing film 240. However, the protective film 235 may at least cover the vibrating arms 135 and is not limited being configured to cover substantially the entire surface of the resonator 10.

As illustrated in FIG. 15, in the resonance device 1, the holding portion 140 of the resonator 10 is disposed on and joined to the side wall 23 of the bottom cover 20, and in addition, the holding portion 140 of the resonator 10 and the side wall 33 of the top cover 30 are joined together. The resonator 10 is held between the bottom cover 20 and the top cover 30 in this manner, and the vibration space in which the vibration arms 135 vibrate is formed by the bottom cover 20, the top cover 30, and the holding portion 140 of the resonator 10. In addition, terminals T4 are formed on the upper surface of the top cover 30 (a surface of the top cover 30 that is opposite to the surface of the top cover 30 facing the resonator 10). The terminals T4 and the resonator 10 are electrically connected to each other by through electrodes V3, connection wiring lines 70, and contact electrodes 76A and 76B.

The top cover 30 is formed of a Si substrate L3 that has a predetermined thickness. The top cover 30 is joined to the holding portion 140 of the resonator 10 at its peripheral portion (the side wall 33) by the joint portion 60, which will be described later. The surface of the top cover 30 that faces the resonator 10 is covered with a silicon oxide film L31. The silicon oxide film L31 is made of, for example, silicon dioxide (SiO₂) and is formed on a surface of the Si substrate L3 by oxidation of the surface of the Si substrate L3 or chemical vapor deposition (CVD). Note that it is preferable that the rear surface of the top cover 30 and side surfaces of the through electrodes V3 be also covered with the silicon oxide film L31.

In addition, the getter layer 34 is formed on the surface of the recess 31 of the top cover 30, the surface facing the resonator 10. The getter layer 34 is made of, for example, titanium (Ti) or the like and adsorbs the outgas that is generated in the vibration space. In the top cover 30 according to the present embodiment, the getter layer 34 is formed on substantially the entire surface of the recess 31 that faces the resonator 10, and thus, a decrease in the degree of vacuum in the vibration space can be suppressed.

The through electrodes V3 of the top cover 30 are formed by filling through holes formed in the top cover 30 with an electrically conductive material. The electrically conductive material with which the through holes are filled is, for example, impurity-doped polycrystalline silicon (Poly-Si), copper (Cu), gold (Au), impurity-doped single-crystal silicon, or the like. Each of the through electrodes V3 serves as a wiring line that electrically connects one of the terminals T4 and a voltage application portion 141 to each other.

The bottom plate 22 and the side wall 23 of the bottom cover 20 are integrally formed of the Si wafer L1. In addition, the upper surface of the side wall 23 of the bottom cover 20 is joined to the holding portion 140 of the resonator 10.

In the resonator 10, the holding portion 140, the base portion 130, the vibration arms 135, and the holding arm 110 are integrally formed through the same process. In the resonator 10, a piezoelectric thin film F3 is formed on the Si substrate F2, which is an example of a substrate, so as to cover the Si substrate F2, and in addition, a metal layer E2 is laminated on the piezoelectric thin film F3. The piezoelectric thin film F3 is laminated on the metal layer E2 so as to cover the metal layer E2, and a metal layer E1 is laminated on the piezoelectric thin film F3. The protective film 235 is laminated on the metal layer E1 so as to cover the metal layer E1, and the parasitic capacitance reducing film 240 is laminated on the protective film 235. Note that, in the holding arm 110 and the vibrating portion 120, the piezoelectric thin film F3, the metal layer E2, the metal layer E1, the protective film 235, and the frequency adjustment film 236 correspond to an example of the above-mentioned “device portion”.

As an example of a temperature-characteristic correction layer, the silicon oxide layer F21, which is, for example, silicon dioxide (SiO₂), is formed on the lower surface of the Si substrate F2. As a result, the temperature characteristics can be improved.

Each of the metal layers E1 and E2 has, for example, a thickness of about 0.1 μm to about 0.2 μm and is patterned, by etching or the like, into a desired shape after being formed into a film. A metal that has a body-centered cubic crystal structure is used for the metal layers E1 and E2. More specifically, each of the metal layers E1 and E2 is made by using molybdenum (Mo), tungsten (W), or the like.

The metal layer E1 is formed on, for example, the vibrating portion 120 so as to serve as an upper electrode and formed on the holding arm 110 and the holding portion 140 so as to serve as a wiring line for connecting the upper electrode to an alternating-current power supply that is provided outside the resonator 10.

In contrast, the metal layer E2 is formed on the vibrating portion 120 so as to serve as a lower electrode and formed on the holding arm 110 and the holding portion 140 so as to serve as a wiring line for connecting the lower electrode to a circuit that is provided outside the resonator 10.

The piezoelectric thin film F3 is a piezoelectric thin film that converts voltage applied thereto into vibration. The piezoelectric thin film F3 is made of a material having a wurtzite hexagonal crystal structure and can contain, for example, nitride such as aluminum nitride (AlN), scandium aluminum nitride (ScAlN), zinc oxide (ZnO), gallium nitride (GaN), or indium nitride (InN) or an oxide as a main component. Note that scandium aluminum nitride is obtained by replacing part of aluminum in aluminum nitride with scandium, and part of aluminum in aluminum nitride may be replaced with two elements such as magnesium (Mg) and niobium (Nb), magnesium (Mg) and zirconium (Zr), or the like instead of being replaced with scandium. In addition, although the piezoelectric thin film F3 has a thickness of, for example, 1 μm, the piezoelectric thin film F3 can have a thickness of about 0.2 μm to about 2 μm.

The piezoelectric thin film F3 expands and contracts in an in-plane direction of the XY plane, that is, the Y-axis direction, in response to an electric field being applied to the piezoelectric thin film F3 by the metal layers E1 and E2. The expansion and contraction of the piezoelectric thin film F3 causes the vibration arms 135 to displace their free ends toward the inner surface of the bottom cover 20 and the inner surface of the top cover 30 and vibrate in the out-of-plane bending vibration mode.

In the present embodiment, an electric field that is applied to the outer vibration arms 135A and 135D and an electric field that is applied to the inner vibration arms 135B and 135C are set to have opposite phases. As a result, the outer vibration arms 135A and 135D are displaced in a direction opposite to a direction in which the inner vibration arms 135B and 135C are displaced. For example, when the outer vibration arms 135A and 135D displace their free ends toward the inner surface of the top cover 30, the inner vibration arms 135B and 135C displace their free ends toward the inner surface of the bottom cover 20.

The protective film 235 prevents oxidation of the metal layer E2, which is the upper electrode for piezoelectric vibration. It is preferable that the protective film 235 be made of a material that is reduced in mass by etching at a rate lower than the rate at which the frequency adjustment film 236 is reduced in mass by etching. The mass reduction rate is expressed by the product of the etching rate, that is, the thickness that is removed per unit time, and the density. The protective film 235 is formed of, for example, a piezoelectric film such as aluminum nitride (AlN), scandium aluminum nitride (ScAlN), zinc oxide (ZnO), gallium nitride (GaN), or indium nitride (InN), or an insulating film such as silicon nitride (SiN), silicon dioxide (SiO₂), or alumina oxide (Al₂O₃). The thickness of the protective film 235 is, for example, about 0.2 μm.

The frequency adjustment film 236 is formed over substantially the entire surface of the vibrating portion 120 and then undergoes a process such as etching so as to be formed only in a predetermined region. The frequency adjustment film 236 is made of a material that is reduced in mass by etching at a rate higher than the rate at which the protective film 235 is reduced in mass by etching. More specifically, the frequency adjustment film 236 is made of a metal such as molybdenum (Mo), tungsten (W), gold (Au), platinum (Pt), nickel (Ni), or titanium (Ti).

Note that the magnitude relationship between the etching rate of the protective film 235 and the etching rate of the frequency adjustment film 236 is arbitrary as long as the protective film 235 and the frequency adjustment film 236 have the above-mentioned relationship in mass reduction rate.

The parasitic capacitance reducing film 240 is made of tetraethyl orthosilicate (TEOS). The thickness of the parasitic capacitance reducing film 240 is about 1 μm. The parasitic capacitance reducing film 240 reduces a parasitic capacitance that is generated in a routing wiring portion and has a function as an insulating layer when wiring lines that have different potentials cross each other and a function as a standoff for expanding the vibration space.

The connection wiring lines 70 are electrically connected to the terminals T4 by the through electrodes V3 and electrically connected to the contact electrodes 76A and 76B.

The contact electrode 76A is formed so as to be in contact with the metal layer E1 of the resonator 10 and electrically connects one of the connection wiring lines 70 and the resonator 10 to each other. The contact electrode 76B is formed so as to be in contact with the metal layer E2 of the resonator 10 and electrically connects the other connection wiring line 70 and the resonator 10 to each other. More specifically, when the contact electrode 76A and the metal layer E1 are connected to each other, the piezoelectric thin film F3, the protective film 235, and the parasitic capacitance reducing film 240, which are laminated on the metal layer E1, are partially removed in such a manner that the metal layer E1 is exposed, and a via V1 is formed. A material that is similar to as the material of the contact electrode 76A is injected into the formed via V1, and the metal layer E1 and the contact electrode 76A are connected to each other. Similarly, when the contact electrode 76B and the metal layer E2 are connected to each other, the piezoelectric thin film F3 and the parasitic capacitance reducing film 240, which are laminated on the metal layer E2, are partially removed in such a manner that the metal layer E2 is exposed, and a via V2 is formed. The contact electrode 76B is injected into the formed via V2, and the metal layer E2 and the contact electrode 76B are connected to each other. The contact electrodes 76A and 76B are made of, for example, a metal such as aluminum (Al), gold (Au), or tin (Sn). Note that it is preferable that the metal layer E1 and the contact electrode 76A be connected to each other in a region outside the vibrating portion 120 and that the metal layer E2 and the contact electrode 76B be connected to each other in a region outside the vibrating portion 120, and in the present embodiment, they are connected to each other in the holding portion 140.

The joint portion 60 is formed in a rectangular ring-like shape around the vibrating portion 120 of the resonator 10, that is, for example, on the holding portion 140 between the resonator 10 and the top cover 30 along the XY plane. The joint portion 60 joins the resonator 10 and the top cover 30 to each other so as to seal the vibration space of the resonator 10. As a result, the vibration space is hermetically sealed, and a vacuum state is maintained.

In the present embodiment, the joint portion 60 includes a first metal layer 61 that is formed on the resonator 10 and a second metal layer 62 that is formed on the top cover 30, and the first metal layer 61 and the second metal layer 62 are bonded to each other by eutectic bonding, so that the resonator 10 and the top cover 30 are joined together.

Exemplary embodiments of the present invention have been described above. A method of manufacturing a collective substrate according to an embodiment of the present invention includes a step of forming openings into a second substrate such that a first mark is exposed. As a result, the first mark can be visually recognized, and thus, the position of the first mark can be accurately determined. The above manufacturing method further includes a step of forming a device portion onto the upper surface of a second substrate while the first mark is used as a reference. As a result, the alignment accuracy of the device portion can be improved.

In the above-described manufacturing method, the step of forming the openings includes deriving the position of the first mark from the external shape of a first substrate when viewed in plan view and forming the openings into the second substrate on the basis of the derived position of the first mark. As a result, the position of the first mark can be easily derived, and the manufacturing costs of the collective substrate can be reduced.

In the above-described manufacturing method, the step of forming the openings includes deriving the position of the first mark by using infrared light and forming the openings into the second substrate on the basis of the derived position of the first mark. As a result, the openings can be positioned with respect to the first mark with high accuracy.

In the above-described manufacturing method, the method further includes forming a second mark at a position in the lower surface of the first substrate, the position corresponding to the first mark, and the step of forming the openings includes deriving the position of the first mark from the second mark and forming the openings into the second substrate on the basis of the derived position of the first mark. As a result, the openings can be positioned with respect to the first mark with high accuracy.

In the above-described manufacturing method, the step of forming the first mark includes forming a plurality of first marks in the upper surface of the first substrate. As a result, in the case of poor recognition of one of the first marks, another one of the first marks can be used instead.

In the above-described manufacturing method, the step of forming the first mark includes forming four or more first marks in the upper surface of the first substrate. As a result, in the case of poor recognition of one of the first marks, another one of the first marks can easily be used instead.

In the above-described manufacturing method, the first mark is formed in a region that is inside an outer peripheral portion of the collective substrate when the first substrate is viewed in plan view. As a result, formation of the first mark into the outer peripheral portion is avoided, so that poor recognition of the first mark due to scratches, contamination, or the like can be suppressed.

In the above-described manufacturing method, the step of forming the first mark includes forming a recess in the upper surface of the first substrate. As a result, the collective substrate, which is a CSOI, can be manufactured.

In a collective substrate according to an embodiment of the present invention, a second substrate has openings that are formed at positions corresponding to a first mark. As a result, the first mark can be visually recognized, and thus, the position of the first mark can be accurately determined. Therefore, for example, the alignment accuracy of a device portion that is formed while the first mark is used as a reference can be improved.

In the above-described collective substrate, a second substrate further include the device portion that is formed on the upper surface thereof while the first mark is used as a reference. As a result, the alignment accuracy of the device portion can be easily improved.

In the above-described collective substrate, the first substrate further includes a second mark that is formed at a position in the lower surface thereof, the position corresponding to the first mark. As a result, by deriving the position of the first mark from the second mark, the openings can be positioned with respect to the first mark with high accuracy.

In the above-described collective substrate, the first substrate has a plurality of first marks that are formed in the upper surface thereof. As a result, in the case of poor recognition of one of the first marks, another one of the first marks can be used instead.

In the above-described collective substrate, the first substrate has four or more first marks that are formed in the upper surface thereof. As a result, in the case of poor recognition of one of the first marks, another one of the first marks can be easily used instead.

In the above-described collective substrate, the first mark is positioned in a region that is inside the outer peripheral portion of the collective substrate when the first substrate is viewed in plan view. As a result, formation of the first mark into the outer peripheral portion is avoided, so that poor recognition of the first mark due to scratches, contamination, or the like can be suppressed.

In the above-described collective substrate, the first substrate further has the recess 21 that is formed in the upper surface thereof. As a result, the collective substrate, which is a CSOI, can be configured.

The above-described collective substrate further includes a third substrate that is joined to the upper surface of the second substrate. As a result, by dividing the collective substrate, a resonance device that includes the first substrate and the second substrate and further includes the third substrate can be manufactured.

Note that the embodiments have been described above for ease of understanding of the present invention and are not intended to limit the scope of the present invention. Changes and improvements may be made to the present invention within the scope of the present invention, and the present invention includes equivalents thereof. In other words, design changes may be suitably made to the embodiments by those skilled in the art, and such embodiments are also within the scope of the present invention as long as they have the features of the present invention. For example, the elements included in the embodiments and the arrangements, materials, conditions, shapes, sizes and so forth of the elements are not limited to those described above as examples, and they may be suitably changed. In addition, the embodiments are examples. It is obvious that the configurations according to different embodiments may be partially replaced with each other or may be combined with each other, and embodiments obtained as a result of such replacements and combinations are also within the scope of the present invention as long as they have the features of the present invention.

### REFERENCE SIGNS LIST

1 resonance device
10 resonator
20 bottom cover
21 recess
22 bottom plate
23 side wall
30 top cover
31 recess
33 side wall
34 getter layer
60 joint portion
61 first metal layer
62 second metal layer
70 connection wiring line
76A, 76B contact electrode
100 collective substrate
110 holding arm
120 vibrating portion
130 base portion
135, 135A, 135B, 135C, 135D vibration arm
140 holding portion
141 voltage application portion
235 protective film
236 frequency adjustment film
240 parasitic capacitance reducing film
330 first substrate
350 second substrate
al opening
A1 first mark
A2 second mark
CP outer peripheral portion
DP device portion
E1, E2 metal layer
F2 Si substrate
F3 piezoelectric thin film
F21 silicon oxide layer
G anchor portion
L1 Si wafer
L3 Si substrate
L31 silicon oxide film
NT notch
OP opening
P virtual plane
S300 manufacturing method
T4 terminal
V1, V2 via
V3 through electrode

1. A method of manufacturing a collective substrate, the method comprising:
forming at least one first mark in or on a first main surface of a first substrate;
joining the first main surface of the first substrate and a first main surface of a second substrate to each other;
forming an opening in the second substrate such that the first mark is exposed therein; and
forming a device portion in or on a second main surface of the second substrate while using the first mark as a reference.

2. The method of manufacturing a collective substrate according to claim 1, wherein the opening is formed by deriving a position of the at least one first mark from an external shape of the first substrate when viewed in a plan view and forming the opening based on the position.

3. The method of manufacturing a collective substrate according to claim 1, wherein the opening is formed by deriving a position of the at least one first mark using infrared light and forming the opening based on the position.

4. The method of manufacturing a collective substrate according to claim 1,
further comprising forming a second mark at a position in or on a second main surface of the first substrate, the position corresponding to the at least one first mark, and
wherein the opening is formed by deriving a position of the at least one first mark from the second mark and forming the opening based on the position.

5. The method of manufacturing a collective substrate according to claim 1, wherein the forming of the at least one first mark includes forming a plurality of first marks in or on the first main surface of the first substrate.

6. The method of manufacturing a collective substrate according to claim 1, wherein the forming of the at least one first mark includes forming four or more first marks in or on the first main surface of the first substrate.

7. The method of manufacturing a collective substrate according to claim 1, wherein the first mark is formed in a region that is inside an outer peripheral portion of the first substrate when the first substrate is viewed in plan view.

8. The method of manufacturing a collective substrate according to claim 1, wherein the forming of the at least one first mark includes forming a recess in the first main surface of the first substrate.

9. The method of manufacturing a collective substrate according to claim 1, further comprising forming a recess in the first main surface of the first substrate, and wherein the forming of the at least one first mark in or on the first main surface of the first substrate is carried out using a position of the recess as a reference.

10. The method of manufacturing a collective substrate according to claim 1, further comprising:
joining a third substrate to the second main surface of the second substrate.

11. A collective substrate comprising:
a first substrate having at least one first mark in or on a first main surface thereof; and
a second substrate joined to the first main surface of the first substrate, the second substrate having an opening therein at a position that corresponds to the first mark.

12. The collective substrate according to claim 11, wherein the second substrate further includes a device portion in or on a second main surface thereof.

13. The collective substrate according to claim 11, wherein the first substrate further includes a second mark at a position in or on a second main surface thereof that corresponds to the first mark.

14. The collective substrate according to claim 11, wherein the first substrate has a plurality of first marks in or on the first main surface thereof.

15. The collective substrate according to claim 11, wherein the first substrate has four or more first marks in or on the first main surface thereof.

16. The collective substrate according to claim 11, wherein the first mark is positioned in a region that is inside an outer peripheral portion of the first substrate when the first substrate is viewed in plan view.

17. The collective substrate according to claim 11, wherein the first substrate further includes a recess in the first main surface.

18. The collective substrate according to claim 11, further comprising:
a third substrate joined to a second main surface of the second substrate.
